(19) United States
(12) Patent Application Publication
(10) Pub. No.: US 2021/0335625 A1
(43) Pub. Date: Oct. 28, 2021

(54) DRY ETCHING APPARATUS AND DRY ETCHING METHOD

(71) Applicant: Hitachi High-Technologies Corporation, Minato-ku, Tokyo (JP)

(72) Inventors: Naoyuki KOFUJI, Tokyo (JP); Kenichi KUWAHARA, Tokyo (JP)

(21) Appl. No.: 16/495,652

(22) PCT Filed: Feb. 8, 2019
(86) PCT No.: PCT/JP2019/004577

§ 371 Date: Sep. 19, 2019

(51) Int. Cl. H01L 21/311; H01J 37/32

(52) U.S. Cl. CPC H01L 21/31138; H01J 2237/334; H01J 37/32009

(57) ABSTRACT

According to a dry etching method using plasma, when an organic film is etched, a first step of irradiating an organic film of a sample only with oxygen radicals while Ar ions are shielded, and a second step of irradiating the organic film with ions of a noble gas are alternately repeated, thereby an accurate etching process can be performed while a variation in etching of the organic film is suppressed. This makes it possible to suppress collapse of an LS pattern formed in a silicon substrate or the like.

### TECHNICAL FIELD

The present invention relates to a dry etching method and a dry etching apparatus.

### BACKGROUND ART

In a manufacturing process of a semiconductor device, it is required to meet size reduction and integration of components to be contained in semiconductor equipment. For example, a small structure such as a nanoscale structure is recently required in an integrated circuit or a nanoelectromechanical system.

A lithography technique is typically used in the manufacturing process of the semiconductor device. In the technique, a pattern of a device structure is applied on a resist layer, and a substrate exposed through the resist layer pattern is selectively removed by etching. An integrated circuit can be formed by depositing another material in such an etched region in a subsequent processing step.

However, it is still difficult to manufacture the nanoscale structure in high throughput using such a technique, and thus various types of technical improvement have been achieved.

Examples of such prior arts include a technique disclosed in patent literature 1. As shown in FIG. 1, the patent literature describes the technique, in which a self-assembled block copolymer (DSA) of polystyrene (PS) 1 and polymethylmethacrylate (PMMA) 2 is formed, and then only the PMMA 2 is removed by etching. The patent literature 1 further describes that a line-and-space pattern (hereinafter, referred to as LS pattern) of PS1 is formed as shown in FIG. 2 by using such a method.

Other known examples include a technique described in patent literature 2. The patent literature 2 discloses a dry etching apparatus to generate plasma by ECR resonance of a magnetic field and a microwave, which is structured such that a dielectric plate with many through-holes is placed between a sample and a dielectric window.

The apparatus is designed such that a position of a region having a magnetic field strength of 875 gauss (called ECR region) is located above the plate with many through-holes. This makes it possible to irradiate the sample only with electrically neutral particles such as radicals in plasma including ions and the radicals generated therein while electrically charged particles, that is, the ions are shielded.

On the other hand, it is possible to irradiate the sample with both the ions and the radicals by locating the position of the ECR region below the plate.

### CITATION LIST

### Patent Literature

Patent literature 1: Japanese Unexamined Patent Application Publication No. 2014-75578.
Patent literature 2: International Patent Publication 2016/190036.

### SUMMARY OF INVENTION

### Technical Problem

However, when an LS pattern is formed by an etching process using plasma after forming an organic film on the sample, the LS pattern produced by the etching may collapse.

An object of the invention is therefore to provide a dry etching method and a dry etching apparatus, which each suppress collapse of the LS pattern during etching of the organic film, and thus secure an accurate etching process.

### Solution to Problem

To solve the above problem, a typical dry etching method of the invention is accomplished by alternately repeating a first step of allowing neutral radicals to be adsorbed by a surface of an organic film in a first atmosphere having a decreased concentration of ions of a noble gas or nitrogen in plasma, and a second step of supplying the ions of the noble gas or nitrogen to the surface of the organic film in a second atmosphere having a higher ion concentration than the first atmosphere.

### Advantageous Effects of Invention

According to the invention, collapse of the LS pattern is suppressed specifically during etching of the organic film, and thus the etching process can be accurately performed.

Other issues, configurations, and effects will be clarified by the following description of embodiments.

### BRIEF DESCRIPTION OF DRAWINGS

FIG. 1 is an enlarged cross-sectional view of a DSA sample before an etching process of PMMA.

FIG. 2 is an enlarged cross-sectional view of a DSA sample after being subjected to an ideal PMMA etching process.

FIG. 3 is a schematic configuration diagram of a dry etching apparatus of this embodiment.

FIG. 4 is an enlarged cross-sectional view of a DSA sample after being subjected to a conventional PMMA etching process in a first comparative example.

FIG. 5 is an enlarged top-down view of the DSA sample after a conventional PMMA etching process in a first comparative example.

FIG. 6 is a view for explaining a cause of collapse of a LS pattern during the conventional PMMA etching process in a first comparative example.

FIG. 7 is a view schematically illustrating a surface state of a sample during a first step of the invented PMMA etching process in a first comparative example.

FIG. 8 is a view schematically illustrating a surface state of a sample during the invented PMMA etching process in a first comparative example.

FIG. 9 is a view schematically illustrating a surface state of the sample during the invented PMMA etching process in a first comparative example.

FIG. 10 is an enlarged cross-sectional view of a DSA sample after an invented PMMA etching process in the first example.

FIG. 11 is an enlarged top-down view of the DSA sample after the invented PMMA etching process in the first example.

FIG. 12 is a graph showing a relationship between etching amount of PMMA and sample temperature in a first step in the invented PMMA etching process in the second example.

FIG. 13 is an enlarged cross-sectional view of a sample of a three-layer resist before an etching process.

FIG. 14 is an enlarged cross-sectional view of the sample of the three-layer resist after a conventional organic-film etching process in the second comparative example.

FIG. 15 is an enlarged cross-sectional view of a sample of a three-layer resist after an organic-film etching process of a third example.

FIG. 16 is a view showing a configuration of an etching apparatus in the second embodiment.

### DESCRIPTION OF EMBODIMENTS

Hereinafter, some embodiments of the invention are described with reference to drawings.

### First Embodiment

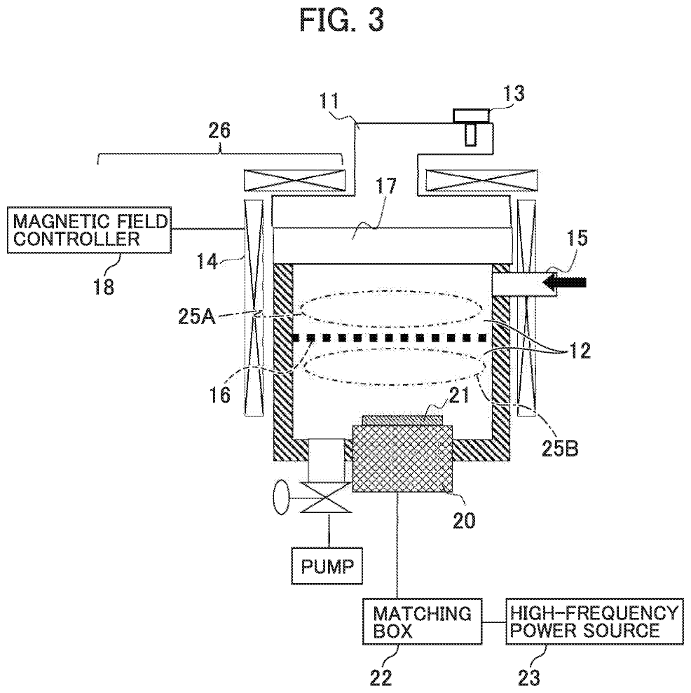

FIG. 3 is a schematic configuration diagram of a downflow-type dry etching apparatus performing a dry etching method of a first embodiment. In the dry etching apparatus of FIG. 3, plasma can be generated in a decompression treatment chamber 12 through ECR resonance caused by a microwave of 2.45 GHz, which is supplied from a magnetron 13 to the decompression treatment chamber 12 via a dielectric window 17 through a waveguide 11, and a magnetic field generated by a solenoid coil 14. A high-frequency power supply 23 is connected via a matching box 22 to a sample stage 20 holding a sample 21.

The magnetron 13 and the solenoid coil 14 configure a plasma generator. The dry etching apparatus further has a plasma controller 26 that controls a plasma generating state in the decompression treatment chamber 12, the solenoid coil 14, and a magnetic-field controller 18 controlling the solenoid coil 14.

In the dry etching apparatus, ion irradiation energy can be controlled from several tens of electron volts to several kilo electron volts by adjusting power supplied from the high-frequency power supply 23. In addition, the sample stage 20, on which the sample 21 is placed, is temperature-regulated, and thus sample temperature is maintained at 20° C. during etching. Furthermore, argon (Ar) gas and oxygen (O₂) gas are introduced into the decompression treatment chamber 12 through a gas inlet 15. The inside of the decompression treatment chamber 12 is decompressed by a vacuum pump.

In the dry etching apparatus, a dielectric plate with many through-hole 16 is placed within the decompression treatment chamber 12. In the dry etching apparatus, plasma is generated near a surface, called ECR surface, having a magnetic field strength of 875 gauss. The magnetic-field controller 18 and the solenoid coil 14, which collectively act as the plasma controller 26, can therefore generate a plasma 25A on a dielectric window side of the plate 16 (i.e., above the plate 16) such that the ECR region is located between the plate 16 and the dielectric window 17. This makes it possible to irradiate the sample 21 only with neutral radicals of oxygen while Ar ions are shielded. In such a state, the sample 21 is placed in the first atmosphere where Ar ion concentration is relatively low.

On the other hand, when the magnetic-field controller 18 controls the solenoid coil 14 to adjust the magnetic field such that the ECR region is located between the plate 16 and the sample 21, plasma 25B can be generated on a sample side of the plate (i.e., below the plate 16). Hence, the sample can be irradiated with both the Ar ions and the neutral radicals of oxygen. In such a state, the sample 21 is placed in the second atmosphere where Ar ion concentration is relatively higher. The Ar ion concentration of the first atmosphere is preferably less than 10% of the ion concentration of the second atmosphere.

The dry etching apparatus capable of performing the dry etching process of the invention may include not only the above-described downflow-type dry etching apparatus but also an RIE type dry etching apparatus.

### Comparative Example 1

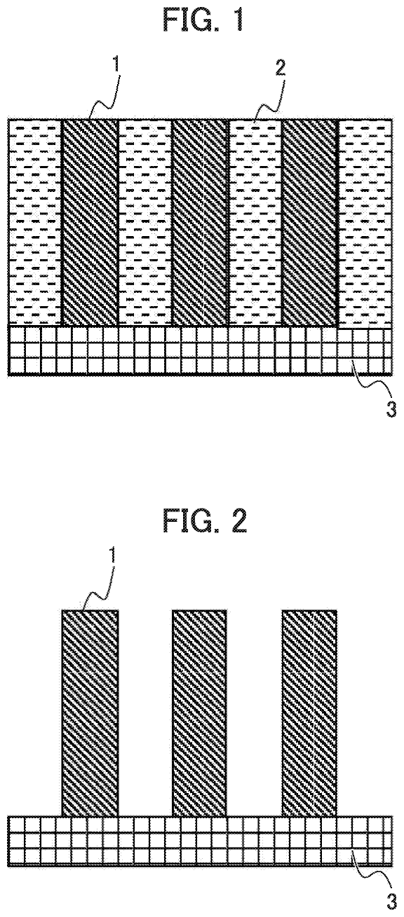

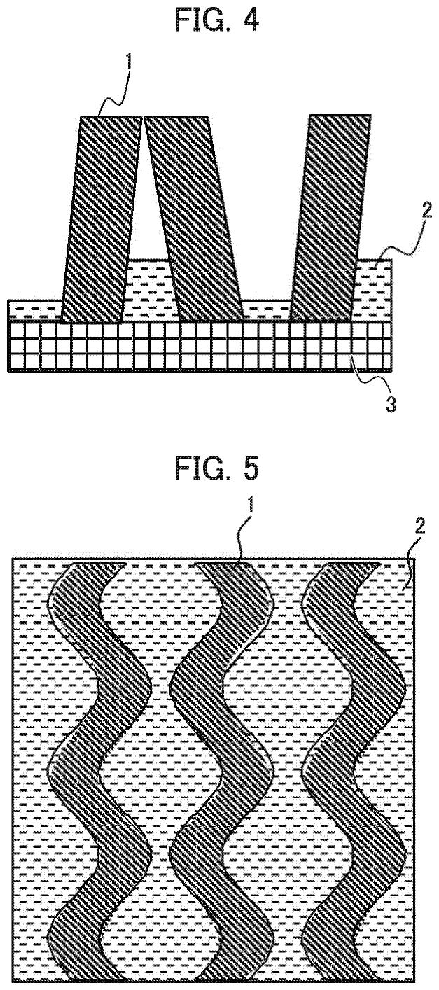

The inventors performed an etching process of PMMA 2 for the DSA sample shown in FIG. 1 using the dry etching apparatus of FIG. 3. In the etching process of a comparative example, first, the ECR region was placed on the sample side of the plate 16, and etching was performed while the sample was irradiated with both the ions and the radicals. FIG. 4 shows results of the etching. The LS pattern of PS1, which would form many walls after the etching process, fell right and left as shown in FIG. 4.

As a result, line edge roughness (LER) which represent pattern distortion increased as shown in a top view of FIG. 5. At a portion where the PS1 significantly fell, adjacent PS1 lines were in contact with each other, and thus ion irradiation was shielded and ions did not reach the PMMA 2 below the portion, so that etching was stopped.

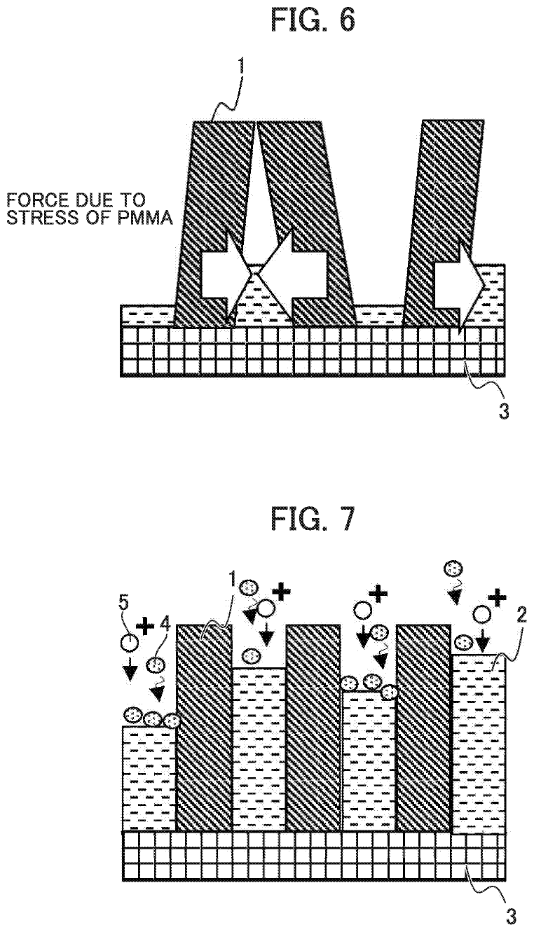

The inventors have investigated a cause of the collapse of the LS pattern using pattern shape evaluation, stress analysis, or the like in the middle of etching. As a result, it has been found that since the PMMA 2 intrinsically has a shrinking (tensile) stress, if a remaining film of the PMMA 2 has a variation in amount, tensile strength increases in a region of a thick remaining film of the PMMA 2 in FIG. 6. The LS pattern is thus pulled and collapses.

Subsequently, the inventors have investigated a cause of the variation in amount of the remaining film of the PMMA 2, i.e., a variation in etching amount of the PMMA 2. While etching proceeds through irradiation of the PMMA 2 with both the oxygen radicals 4 and the Ar ions 5, a variation occurs in the amount of the oxygen radicals 4 that reach the surface of the PMMA 2 as shown in FIG. 7 due to a variation in space distance between the PS1 and the PS1 of the LS pattern. It has been found that since the etching amount of the PMMA 2 is in proportion to the amount of the oxygen radicals 4 that reach the surface of the PMMA 2, the etching amount increases with an increase in the space width, while the etching amount decreases with a decrease in the space width.

The inventors therefore have derived the following etching method, in which two steps are repeated, to suppress the variation in etching amount. In the first step, the ECR region is placed on the dielectric window 17 side of the plate 16 to generate the oxygen plasma 25A (FIG. 3). Consequently, the sample is irradiated with the oxygen radicals in the first atmosphere while the Ar ions are shielded.

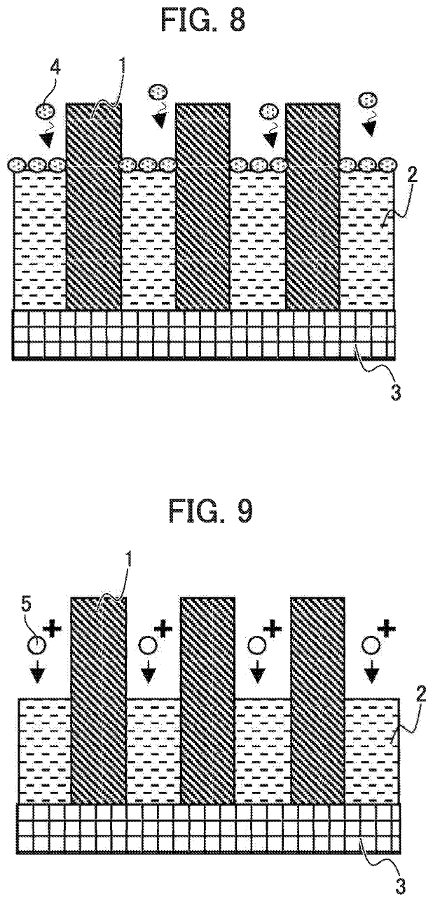

At this time, since the Ar ions are shielded, even if the sample is irradiated with the oxygen radicals, etching does not proceed. When the step time of first step is enough long, all of the surface of the PMMA 2 should be in the state of saturated adsorption as shown in FIG. 8. Here, “saturated adsorption” means a state where substantially no neutral radicals are further adsorbed.

Subsequently, in the second step, the Ar plasma 25B is generated while the ECR region is placed on the sample 21 side of the plate 16 (FIG. 3). Consequently, the PMMA 2 is irradiated with the Ar ions 5 in the second atmosphere. This ion irradiation activates the oxygen radicals 4 adsorbed by the surface of the PMMA 2, and thus etching of the PMMA 2 proceeds as shown in FIG. 9.

Since the etching amount in this case is determined by the amount of the oxygen radicals 4 adsorbed by the surface of the PMMA 2, if the oxygen radicals 4 are adsorbed in a saturated manner by the surface of the PMMA 2, a certain amount of PMMA 2 is etched. Hence, the first step and the second step are alternately repeated, thereby the etching process proceeds with keeping the etching amount of PMMA 2 uniform regardless of a variation in pattern, and thus collapse of the LS pattern is suppressed. The first step is preferably longer in processing time than the second step because effective saturated adsorption is secured thereby.

### Example 1

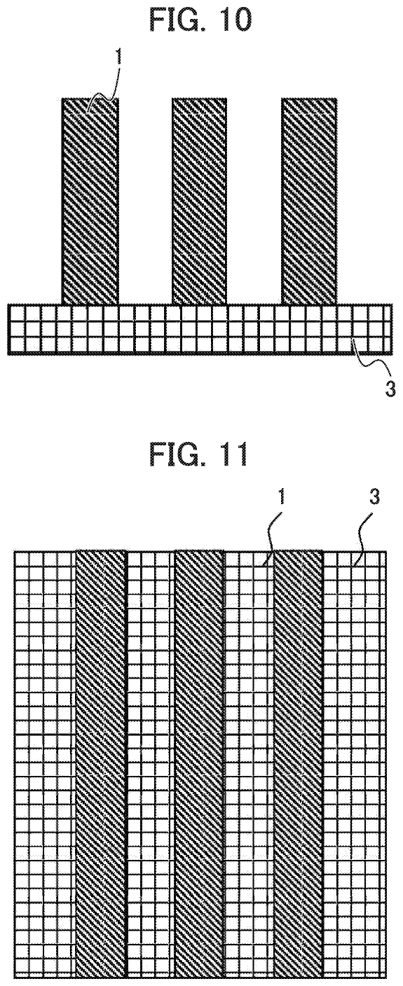

FIG. 10 shows a cross-sectional shape of the sample etched by the above etching method. Collapse of PS1 is not seen. FIG. 11 shows a top-down view of a processed sample. The resultant LS pattern of the PS1 shows no LER caused by collapse, which reveals formation of a straight pattern.

Although oxygen gas has been used in the first step herein, any mixed gas containing oxygen can be used, such as, for example, a gas including oxygen diluted by a noble gas. Furthermore, a gas, which contains no oxygen but can etch an organic material by a chemical reaction may be used, such as, for example, a mixed gas containing hydrogen, water, or methanol. Although Ar gas has been used in the second step, another noble gas or nitrogen gas may be used as long as the gas is configured of only a gas that does not etch the organic film by a chemical reaction. The organic film that can be etched is not limited to PMMA.

### Example 2

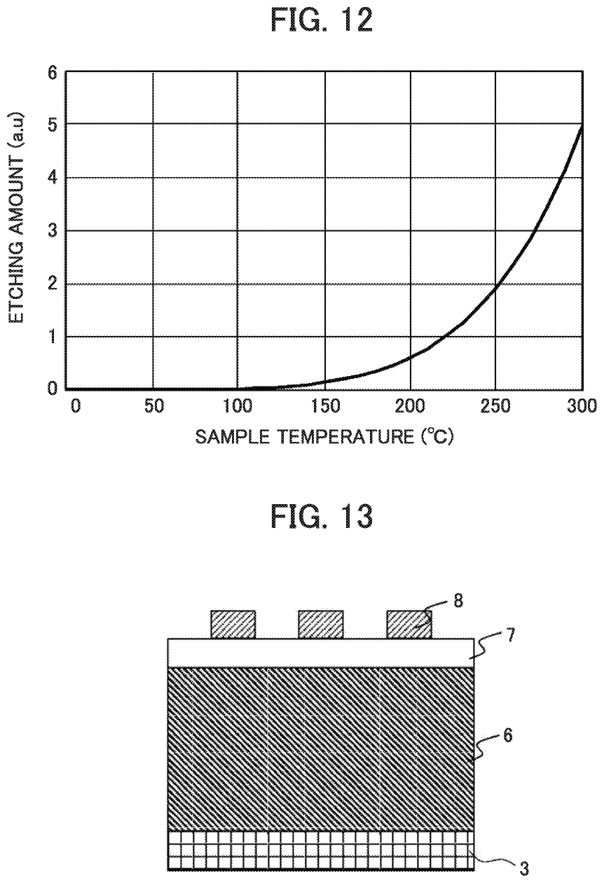

In the Example 1, PMMA was etched while sample temperature was maintained at 20° C. The inventors have investigated influence of the sample temperature. FIG. 12 shows a relationship between the etching amount of the PMMA and the sample temperature during irradiation of the PMMA with the oxygen radicals in the first step. It has been found that no PMMA is etched at 100° C. or lower. On the other hand, if the sample temperature exceeds 100° C., the etching amount of PMMA acceleratingly increases, causing a variation in etching amount.

In addition, it has been found that while collapse of the LS pattern and an increase in LER due to such collapse are not seen at 100° C. or lower, collapse of the LS pattern and an increase in LER due to such collapse abruptly increase at a temperature above 100° C. Therefore, 100° C. can be defined as singularity of wafer temperature. From the above, it is recognized that the sample temperature in the first step is preferably maintained at 100° C. or lower to achieve the effects of the PMMA etching process described in the Example 1.

When the plasma in the first step contains hydrogen radicals, the singularity of wafer temperature is known to be lowered to 50° C. In such a case, the sample temperature is desirably maintained at 50° C. or lower.

### Comparative Example 2

A further example is now described, in which the etching method of the first embodiment is applied to processing of a three-layer resist. As shown in FIG. 13, this processing was performed using a sample, in which an organic film 6 and an inorganic film 7 were stacked on a silicon substrate 3 and a resist mask 8 having a 30-nm-pitch LS pattern was formed on the stack. The thickness of each layer was as follows: 200 nm for the organic film 6, 20 nm for the inorganic film 7, and 20 nm for the resist mask 8.

The inorganic film 7 of this sample was etched by a dry etching process similar to that in the comparative example 1 to form a mask of the inorganic film, and in turn the organic film 6 was etched using the inorganic film mask. In the process similar to that in the comparative example 1, however, the following phenomenon occurred: when the organic film 6 was etched by oxygen or the like, the resultant LS pattern of the organic film 6 fell during etching.

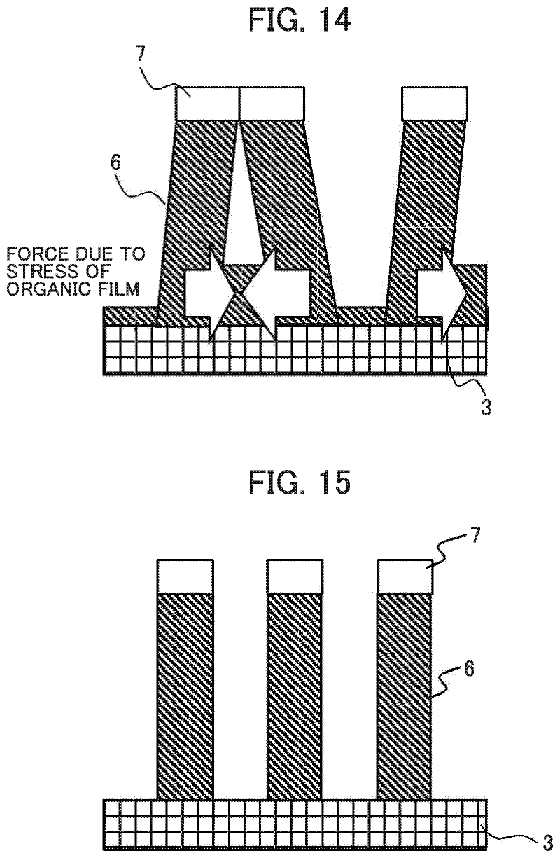

Actually, in a state where the sample was irradiated with both the ions and the neutral radicals, the following phenomenon was seen: adjacent lines of the LS pattern of the organic film 6 were in contact with each other as shown in FIG. 14, and thus etching was stopped. As a result of analysis, it has been found that the amount of a remaining film of the organic film 6 also varies in such a case, and thus the LS pattern of the organic film 6 is pulled and falls to a thick remaining-film side due to the tensile stress of the remaining film of the organic film 6.

### Example 3

A first step, in which a sample was irradiated with oxygen plasma while Ar ions were shielded, and a second step, in which the sample was irradiated with Ar plasma while Ar ions were not shielded, were therefore repeated as in the Example 1. As a result, etching proceeded with keeping uniform thickness of the remaining film of the organic film 6. Consequently, the phenomenon, such as collapse of the pattern or contact between lines of the pattern, did not occur as shown in FIG. 15.

### Second Embodiment

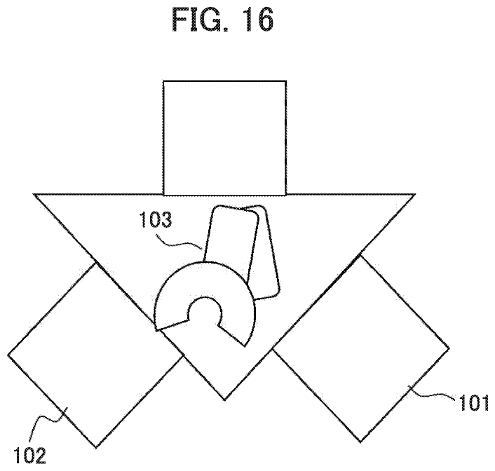

FIG. 16 shows a dry etching apparatus, in which a downflow type etcher 101 is interlocked to a reactive ion etching (RIE)-type etcher 102 by a vacuum transfer unit 103. In the first step of a second embodiment, a sample is transferred into the downflow type etcher (first device) 101 and irradiated with oxygen plasma.

Since the downflow type etcher 101 has a structure where the sample is irradiated only with neutral radicals in plasma while ions in the plasma are shielded, the sample is irradiated only with oxygen radicals in the first atmosphere. Since PMMA is not etched only by the oxygen radicals, oxygen radicals are adsorbed in a saturated manner on the PMMA surface.

Subsequently, in the second step, the sample is transferred from the downflow type etcher 101 to the reactive ion etcher (second device) 102 by the vacuum transfer unit (transfer device) 103, and Ar plasma is generated within the reactive ion etcher 102. In the reactive ion etcher 102, since the sample is irradiated with both the ions and the neutral radicals in the plasm, PMMA in the sample is irradiated with Ar ions in the second atmosphere. As with the example as shown in FIG. 9, this ion irradiation activates oxygen radicals adsorbed on the PMMA surface, and thus PMMA etching proceeds.

In this case, since the etching amount is determined by the amount of the oxygen radicals adsorbed in a saturated manner on the PMMA surface, a certain amount of PMMA is etched. The sample is repeatedly transferred via the vacuum transfer unit 103 between the downflow type etcher 101 and the reactive ion etcher 102, thereby the first step and the second step can be alternately repeated. As a result, etching proceeds while the PMMA remaining film is maintained uniform, and thus collapse of the LS pattern is suppressed.

A sample etched in this manner has a cross-sectional shape similar to that shown in FIG. 10, and shows no collapse of the LS pattern. The processed sample has a top-down shape similar to that shown in FIG. 11. No LER caused by collapse is seen in the resultant LS pattern of the PS, showing formation of a straight pattern.

The invention is not limited to the above-described embodiments, and includes various modifications. For example, the embodiments have been described in detail to clearly explain the invention, and the invention is not necessarily limited to the embodiments each having all the described configurations. In addition, part of a configuration of one embodiment can be substituted for a configuration of another embodiment, and a configuration of one embodiment can be added to a configuration of another embodiment. Furthermore, a configuration of one embodiment can be added to, removed from, or substituted for part of a configuration of another embodiment.

### LIST OF REFERENCE SIGNS

1 Polystyrene (PS), 2 Polymethylmethacrylate (PMMA), 3 Silicon substrate, 4 Oxygen radical, 5 Ar ion, 6 Organic film, 7 Inorganic film, 8 Resist mask, 11 Waveguide, 12 Decompression treatment chamber, 13 Magnetron, 14 Solenoid coil, 16 plate with many through-hole, 17 Dielectric window, 20 Sample stage, 21 Sample, 22 Matching box, 23 High-frequency power supply, 101 Downflow type etcher, 102 RIE etcher, 103 Vacuum transfer unit, 200 Silicon, 202 Silicon oxide film

1. A dry etching method of an organic film,
wherein a first step of allowing neutral radicals to be adsorbed by a surface of an organic film in a first atmosphere having a decreased concentration of ions of a noble gas or nitrogen in plasma, and a second step of supplying the ions of the noble gas or nitrogen to the surface of the organic film in a second atmosphere having a higher ion concentration than the first atmosphere are alternately repeated.

2. The dry etching method according to claim 1, wherein the neutral radicals are radicals of oxygen or hydrogen.

3. The dry etching method according to claim 1, wherein the noble gas is argon gas.

4. The dry etching method according to claim 1, wherein the organic film is made of PMMA.

5. The dry etching method according to claim 1, wherein in the first step, the neutral radicals are adsorbed in a saturated manner by the organic film.

6. The dry etching method according to claim 1, wherein the first step has a longer processing time than the second step.

7. A dry etching apparatus performing the dry etching method according to claim 1, comprising:
a plasma generator that generates plasma in a decompression treatment chamber;
a plate with many through-hole placed in the decompression treatment chamber; and
a plasma controller capable of changing a generation position of the plasma to be above or below the plate.

8. A dry etching apparatus performing the dry etching method according to claim 1, comprising:
a first device that irradiates an organic film of a sample with neutral radicals in the first atmosphere;
a second device that irradiates the organic film of the sample with ions of a noble gas or nitrogen in the second atmosphere; and
a transfer device that transfers the sample from the first device to the second device, or from the second device to the first device.
